(19) United States
(12) Patent Application Publication
(10) Pub. No.: US 2009/0309641 A1
(43) Pub. Date: Dec. 17, 2009

(54) DUAL MODE EDGE TRIGGERED FLIP-FLOP

(76) Inventor: Woo-Hyun Park, Gangnam-gu (KR)

Correspondence Address: SHERR & VAUGHN, PLLC, 620 HERNDON PARKWAY, SUITE 320, HERNDON, VA, 20170, US

(21) Appl. No.: 12/482,298

(22) Filed: Jun. 10, 2009

(30) Foreign Application Priority Data
Jun. 17, 2008 (KR) 10-2008-0056761

(51) Int. Cl. H03K 3/289

(52) U.S. Cl. 327/203; 327/202

(57) ABSTRACT

An edge triggered flip-flop including at least one inverter and at least one transmission gate section. Each transmission gate section includes an upper part having a first transmission gate and a second transmission gate connected in series, the first transmission gate being controlled in accordance with a clock signal, and the second transmission gate being controlled in accordance with an enable clock signal. Each transmission gate section also includes a lower part having a third transmission gate and a fourth transmission gate connected in series, the third transmission gate being controlled complementarily to the first transmission gate in accordance with the clock signal, and the fourth transmission gate being controlled complementarily to the second transmission gate in accordance with the enable clock signal.

The present application claims priority under 35 U.S.C. 119 to Korean Patent Application No. 10-2008-0056761 (filed on Jun. 17, 2008), which is hereby incorporated by reference in its entirety.

### BACKGROUND

ASIC (Application Specific Integrated Circuit) semiconductor design is applied to semiconductor products or devices for various purposes, and is useful in achieving distinctness and high performance in a device in which a semiconductor is used.

In general, designers for ASIC semiconductors use a library, which is a semifinished product constructed in advance, for ease of design. In such a library, a standard cell is widely used. Flip-flops are used in implementation of an operation to store and output data in a logic circuit, which operates in accordance with a clock. The ASIC library provides such flip-flops.

The flip-flops store and output one-bit data at a rising edge at which a clock is changed from a low level to a high level, or a falling edge at which a clock is changed from a high level to a low level. The flip-flops include a D flip-flop, a T flip-flop, a JK flip-flop, and the like, and are used in various ways for various purposes.

FIG. 1 is a circuit diagram of a related edge triggered D flip-flop that operates at a rising edge and is widely used at the time of ASIC semiconductor design. The known D flip-flop includes a master section 100 that stores and outputs data D when a clock signal CK is at a low level, and a slave section 100 that outputs data D output from the master section 100 to the outside when the clock signal CK is at a high level. This circuit further includes a three-state buffer 124 that outputs data D output from the master section 100 to the slave section 110 when the clock signal CK is at the high level, and three-state buffers 132 and 134 that feeds back data D output from the slave section 110 to the master section 100 when the clock signal CK is at the high level.

The above-described related circuit is the D flip-flop that operates only at the rising edge. Accordingly, in the case of design for a circuit, which operates at both the rising edge and the falling edge, an additional falling edge D flip-flop needs to be provided. The addition of the falling edge operation requires a doubling of a chip area, inefficiently making circuit design complicated and inconvenient. In addition, with respect to a clock signal that is used in the falling edge flip-flop, buffering needs to be performed in order to match clock skew with the clock signal, which is used in the rising edge flip-flop. As a result, a more chip area is needed, and unnecessary power consumption is caused by buffering.

### SUMMARY

Embodiments relate to an edge triggered flip-flop. In particular, the present invention provides a D flip-flop, as a flip-flop for an ASIC library capable of being used at both a rising edge and a falling edge.

Embodiments relate to an edge triggered flip-flop including at least one inverter and at least one transmission gate section. Each transmission gate section includes an upper part having a first transmission gate and a second transmission gate connected in series, the first transmission gate being controlled in accordance with a clock signal, and the second transmission gate being controlled in accordance with an enable clock signal. Each transmission gate section also includes a lower part having a third transmission gate and a fourth transmission gate connected in series, the third transmission gate being controlled complementarily to the first transmission gate in accordance with the clock signal, and the fourth transmission gate being controlled complementarily to the second transmission gate in accordance with the enable clock signal.

When the enable clock signal is at a logic high level, the edge triggered flip-flop may operate in a rising edge mode with respect to the clock signal, and when the enable clock signal is at a logic low level, the edge triggered flip-flop operates in a falling edge mode with respect to the clock signal.

In each transmission gate section, when the enable clock signal is at a logic high level, the second transmission gate may be turned on, and the fourth transmission gate may be turned off, and when the enable clock signal is at a logic low level, the second transmission gate may be turned off, and the fourth transmission gate may be turned on.

Each transmission gate section may include at least one of a first type of a transmission gate section in which, when the clock signal is at a logic high level, the first and second transmission gates are both turned on, and when the clock signal is at a logic low level, the third and fourth transmission gates are both turned on, and a second type of a transmission gate section in which, when the clock signal is at the logic low level, the first and second transmission gates are both turned on, and when the clock signal is at the logic high level, the third and fourth transmission gates are both turned on.

The first to fourth transmission gates may individually include first to fourth NMOS transistors, and first to fourth PMOS transistors, each of which has the common source and drain with a corresponding one of the first to fourth NMOS transistors, and complementary signals are input to the gates of an NMOS transistor and a PMOS transistor belonging to the same transmission gate.

The logic high level may be at a power supply voltage, and the logic low level may be at a ground voltage.

The edge trigger flip-flop may be designed to operate in either the rising edge mode or the falling edge mode at the time of application of the enable clock signal at a fixed voltage.

According to embodiments, the dual-pass transistor structure ensures that the flip-flop is controlled so as to operate in a rising edge mode or a falling edge mode in accordance with the enable clock signal. Therefore, in the case of design for a system, which requires the two modes, a chip area, the number of output pins, and the number of clock lines can be reduced. As a result, line efficiency can be improved.

The use of the ASIC flip-flop library can be reduced, and an additional processing, such as clock buffering, can be eliminated or simplified. Thus, the design time can be reduced, and stable design can be performed. In addition, since an additional buffer cell does not need to be used, area and power consumption can be reduced.

Two transistors may be used to form a transmission gate type switch. Therefore, the driving ability with respect to the clock signal becomes better, allowing advantageous designs for high-frequency systems to be made, as compared with the related circuit using a single-pass transistor.

### DRAWINGS

FIG. 1 is a circuit diagram of a related edge triggered D flip-flop that operates at a rising edge.

Example FIG. 2 is a circuit diagram of a clocked three-state buffer having an inverter and a transmission gate.

Example FIG. 3 is a circuit diagram of a clocked three-state buffer having two PMOS transistors and two NMOS transistors that are connected in series.

Example FIG. 4 is a circuit diagram of a first type of a transmission gate section including an upper part and a lower part, each having two transmission gates.

Example FIG. 5 is a circuit diagram of a second type of a transmission gate section including an upper part and a lower part, each having two transmission gates.

Example FIG. 6 is a circuit diagram of a dual mode edge triggered D flip-flop using a dual-pass transistor switch of Example FIG. 4 or 5.

Example FIG. 7 shows simulation waveforms of a dual mode edge triggered D flip-flop of Example FIG. 6.

Example FIG. 8 is a circuit diagram including a counter using different flip-flops that operate at a rising edge or a falling edge.

### DESCRIPTION

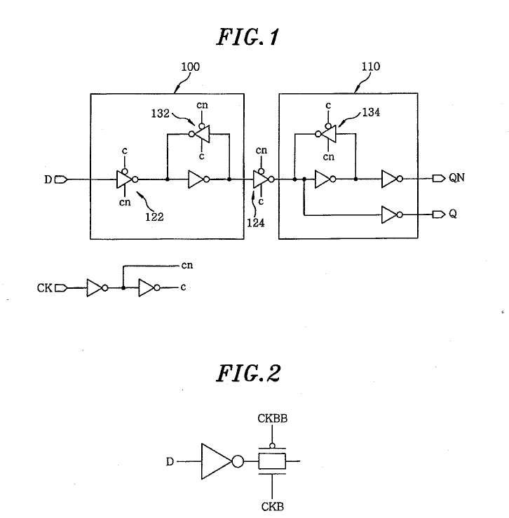

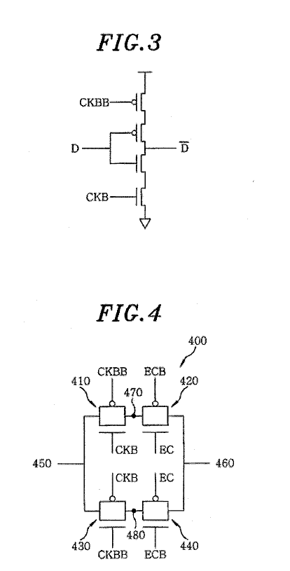

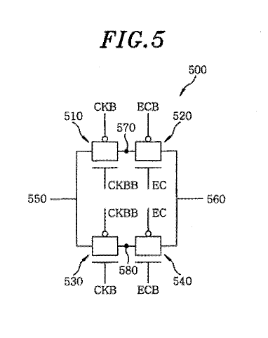

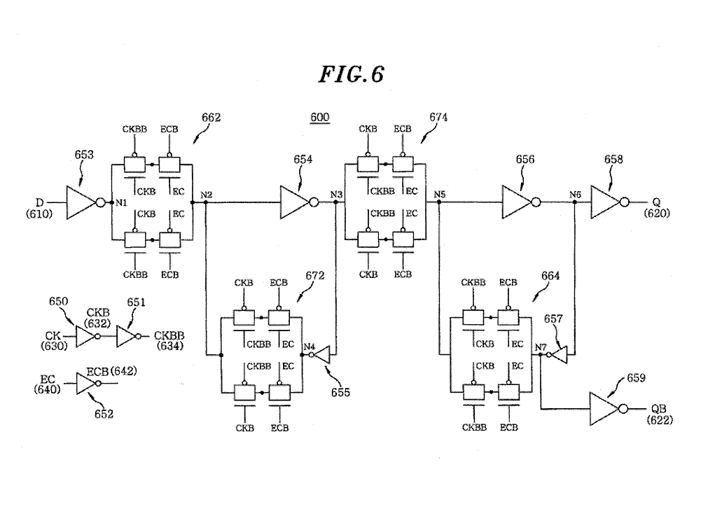

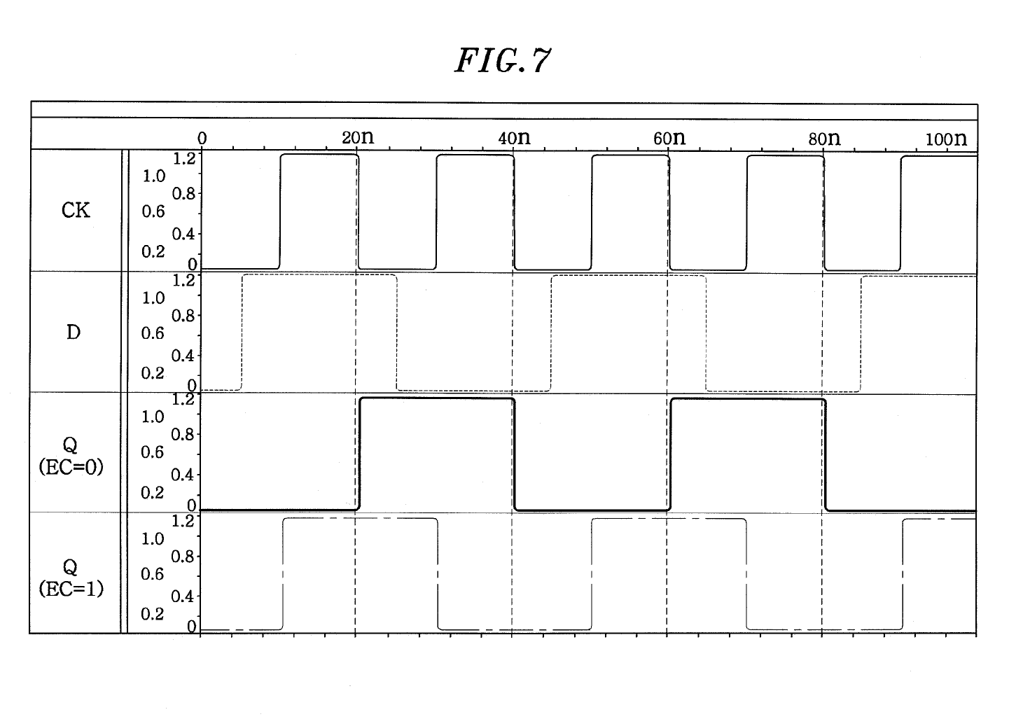

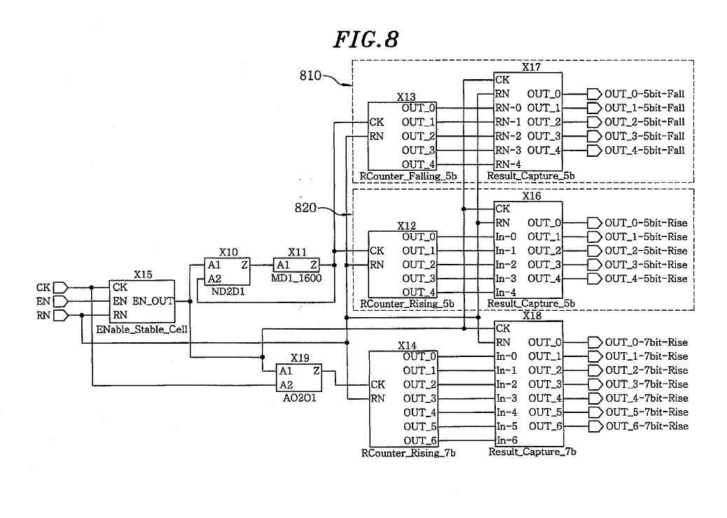

The operation principle of the invention will now be described in detail with reference to the accompanying drawings. Referring to FIG. 1, the related edge triggered D flip-flop that operates at the rising edge includes the master section 100 and the slave part 110. The related edge triggered D flip-flop includes three-state buffers 122, 124, 132, and 134 as constituent elements. The clocked three-state buffers 122, 124, 132, and 134 may be implemented in various ways, for example, circuits having an inverter, as described below.

Example FIG. 2 is a circuit diagram of a clocked three-state buffer including an inverter and a transmission gate. Since this clocked three-state buffer is driven by the parallel combination of an NMOS transistor and a PMOS transistor of the transmission gate, it is suitable for a system that operates at a high frequency, as compared with a circuit that uses a pass transistor having a single NMOS transistor.

Example FIG. 3 is a circuit diagram of a clocked three-state buffer including two PMOS transistors and two NMOS transistors that are connected in series. Each pass transistor to which a clock signal CKB or CKBB is input can only drive a single transistor, and accordingly the circuit of example FIG. 3 operates at a speed inferior to a circuit using a transmission gate and has a limit high-frequency system designs. In addition, if a data signal D is toggled, noise is produced at the output node. For this reason, the circuit of example FIG. 3 is digitally and logically equivalent to the circuit of example FIG. 2, but it is electrically inferior to the circuit of example FIG. 2.

To implement a dual mode edge triggered flip-flop, a switch for selecting a rising edge mode or a falling edge mode in accordance with an enable clock signal is needed. In embodiments, a transmission gate section operating as a switch is implemented by using a dual-pass transistor. This switch includes a part processing an enable clock, in addition to a part of the three-state buffer of example FIG. 2 to which the clock signal CKB or CKBB is applied. As described above, the configuration of example FIG. 2 may be used since it is electrically stable.

Example FIG. 4 is a circuit diagram of a first type of a transmission gate section 400 including an upper part and a lower part, each having two transmission gates. Example FIG. 5 is a circuit diagram of a second type of a transmission gate section 500 including an upper part and a lower part, each having two transmission gates. In the first type of the transmission gate section 400 shown in example FIG. 4 and the second type of the transmission gate section 500 shown in example FIG. 5, a pass transistor that is controlled in accordance with the clock signals CKB and CKBB may be connected in series to a pass transistor, to which the enable clock signals EC and ECB are applied. The transmission gate section 400 of example FIG. 4 and the transmission gate section 500 of example FIG. 5 both may operate as a switch using a dual-pass transistor, except that the clock signals CKB and CKBB are inverted. In embodiments, the pass transistors may be implemented by a transmission gate having a pair of PMOS and NMOS transistors whose sources and drains are common and whose gates are controlled in accordance with complementary signals.

Referring to example FIG. 4, the upper part of the first type of the transmission gate section 400 may be provided with a first transmission gate 410 and a second transmission gate 420 that are connected in series between an input terminal 450 and an output terminal 460. The first transmission gate 410 may be controlled in accordance with complementary clock signals NMOS-CKB and PMOS-CKBB, and the second transmission gate 420 may be controlled in accordance with complementary enable clock signals EC and ECB. The lower part of the first type of the transmission gate section 400 may have a third transmission gate 430 and a fourth transmission gate 440 that are connected in series between the input terminal 450 and the output terminal 460. The third transmission gate 430 may be controlled in accordance with complementary clock signals NMOS-CKBB and PMOS-CKB, and the fourth transmission gate 440 may be controlled in accordance with complementary enable clock signals NMOS-ECB and PMOS-EC.

Referring to example FIG. 5, the upper part of the second type of the transmission gate section 500 may be provided with a first transmission gate 510 and a second transmission gate 520 that are connected in series between an input terminal 550 and an output terminal 560. The first transmission gate 510 may be controlled in accordance with complementary clock signals NMOS-CKBB and PMOS-CKB, and the second transmission gate 520 may be controlled in accordance with complementary enable clock signals NMOS-EC and PMOS-ECB. The lower part of the second type of the transmission gate section 500 may be provided with a third transmission gate 530 and a fourth transmission gate 540 that are connected in series between the input terminal 550 and the output terminal 560. The third transmission gate 530 may be controlled in accordance with complementary clock signals NMOS-CKB and PMOS-CKBB, and the fourth transmission gate 540 may be controlled in accordance with complementary enable clock signals NMOS-ECB and PMOS-EC.

If the enable clock signal EC is at the logic high level, the enable clock signal ECB complementary to the enable clock signal EC becomes the logic low level. When this happens, in the first type of the transmission gate section 400 shown in example FIG. 4, an upper part node 470 is connected to the output terminal 460, and a lower part node 480 is put in a floating state. Then, when the clock signal CKB at the logic high level or the clock signal CKBB at the logic low level is input, a signal at the input terminal 450 is transmitted to the output terminal 460 through the upper part node 470. Meanwhile, in the second type of the transmission gate section 500 shown in example FIG. 5, an upper part node 570 is connected to the output terminal 560, and a lower part node 580 is put in a floating state. Then, when the clock signal CKB at the logic low level or the clock signal at the logic high level is input, a signal at the input terminal 550 is transmitted to the output terminal 560 through the upper part node 570.

Alternatively, if the enable clock signal EC is at the logic low level, the enable clock signal ECB complementary to the enable clock signal EC becomes the logic high level. When this happens, in the first type of the transmission gate section 400 shown in example FIG. 4, the lower part node 480 is connected to the output terminal 460, and the upper part node 470 is put in a floating state. Then, when the clock signal CKB at the logic low level or the clock signal CKBB at the logic high level is input, a signal at the input terminal 450 is transmitted to the output terminal 460 through the lower part node 480. Meanwhile, in the second type of the transmission gate section 500 shown in example FIG. 5, the lower part node 580 is connected to the output terminal 560, and the upper part node 580 is put in a floating state. Then, when the clock signal CKB at the logic high level or the clock signal CKBB at the logic low level is input, a signal at the terminal 550 is transmitted to the output terminal 560 through the lower part node 580.

Example FIG. 6 is a circuit diagram of a dual mode edge triggered D flip-flop 600 using the dual-pass transistor switch of example FIG. 4 or 5. If the dual-pass transistor switch of example FIG. 4 or 5, that is, the first or second type of the transmission gate section 400 or 500 is used, instead of the known pass transistor which is used as a switch of a D flip-flop, the rising edge mode or the falling edge mode can be selectively controlled and used in accordance with an EC signal 640.

In embodiments, the D flip-flop 600 may include a data input terminal (D) 610, a data output terminal (Q) 620, an inverted data output terminal (QB) 622, a clock terminal (CK) 630, an enable clock terminal (EC) 640, a first inverter 650 outputting an inverted signal of the input of the CK terminal 630 to the CKB terminal 632, a second inverter 651 outputting an inverted signal of the input of the CKB terminal 632 to the CKBB terminal 634, a third inverter 652 outputting an inverted signal of the input of the EC terminal 640 to the ECB terminal 642, and a fourth inverter 653 outputting an inverted signal of the input of the D terminal 610 to a node N1. The D flip-flop 600 may further include a first transmission gate section 662 formed by the first type of the transmission gate section 400 so as to output the input of the node N1 to a node N2, a fifth inverter 654 outputting an inverted signal of the input of the node N2 to a node N3, a sixth inverter 655 outputting an inverted signal of the input of the node N3 to a node N4, a second transmission gate section 672 formed by the second type of the transmission gate section 500 so as to output the input of the node N4 to the node N2, a third transmission gate section 674 formed by the second type of the transmission gate section 500 so as to output the input of the node N3 to a node N5, a seventh inverter 656 outputting an inverted signal of the input of the node N5 to a node N6, an eighth inverter 657 outputting an inverted signal of the input of the node N6 to a node N7, a fourth transmission gate section 664 formed by the first type of the transmission gate section 400 so as to output the input of the node N7 to the node N5, a ninth inverter 658 outputting an inverted signal of the input of the node N6 to the Q terminal 620, and a tenth inverter 659 outputting an inverted signal of the input of the node N7 to the QB terminal 622.

When the EC signal 640 is at the logic high level, the circuit 600 of example FIG. 6 operates as a rising edge mode D flip-flop. When a CK signal 630 is at the logic low level, the first transmission gate section 662 and the fourth transmission gate section 664 formed by the first type of the transmission gate section 400 are turned on, and the second transmission gate section 672 and the third transmission gate section 674 formed by the second type of the transmission gate section 500 are turned off. When this happens, previous data is transmitted to the Q terminal 620 serving as the data output terminal. If the CK signal 630 becomes the logic high level, the first transmission gate section 662 and the fourth transmission gate section 664 formed by the first type of the transmission gate section 400 are turned off, and the second transmission gate section 672 and the third transmission gate section 674 formed by the second type of the transmission gate section 500 are turned on. When this happens, data that is input from the D terminal 610 serving as the data input terminal to the output terminal of the first transmission gate section 662 in advance is output to the Q terminal 620. Therefore, at the moment the CK signal 630 becomes the logic high level, an operation to read data of the D terminal 610 is carried out.

When the EC signal 640 is at the logic low level, the circuit 600 of example FIG. 6 operates as a falling edge mode D flip-flop. When the CK signal 630 is at the logic high level, the first transmission gate section 662 and the fourth transmission gate section 664 formed by the first type of the transmission gate section 400 are turned on, and the second transmission gate section 672 and the third transmission gate section 674 formed by the second type of the transmission gate section 500 are turned off. When this happens, previous data is transmitted to the Q terminal 620 serving as the data output terminal. If the CK signal 630 becomes the logic low level, the first transmission gate section 662 and the fourth transmission gate section 664 formed by the first type of the transmission gate section 400 are turned off, and the second transmission gate section 672 and the third transmission gate section 674 formed by the second type of the transmission gate section 500 are turned on. When this happens, data that is input from the D terminal 610 serving as the data input terminal to the output terminal of the first transmission gate section 662 in advance is output to the Q terminal 620. Therefore, at the moment the CK signal 630 becomes the logic low level, an operation to read data of the D terminal 610 is carried out.

Example FIG. 7 shows the simulation waveforms of the dual mode edge triggered D flip-flop 600 shown in example FIG. 6. The simulation is performed using 0.13 um process parameters. It can be seen that, when the EC signal is at the logic high level, the circuit of example FIG. 6 operates as a rising edge mode flip-flop, and when the EC signal is at the logic low level, the circuit of example FIG. 6 operates as a falling edge mode flip-flop.

Example FIG. 8 is a circuit diagram including a counter using different flip-flops that operate at a rising edge and a falling edge, respectively. In other cases, when a flip-flop 810 that operates at the rising edge and a flip-flop 820 that operates at the falling edge are used, ten output pins are used in total, which causes an increase in the chip area and high design complexity. In addition, since the clock signal is applied to two lines, clock buffering needs to be taken into consideration. In contrast, if the dual mode edge triggered flip-flop according to embodiments is used, in a single counter, a flip-flop can operate at both the rising edge and the falling edge. Therefore, only five output pins are provided, which makes it possible to reduce the chip area and design complexity. In addition, since the clock signal is shared by a single line, clock buffering is not taken into consideration much.

The dual mode edge triggered function of t embodiments can also be applied to various kinds of flip-flops, such as a scan-enable flip-flop, a reset flip-flop, a set flip-flop, and the like.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
at least one inverter; and
at least one transmission gate section, wherein each transmission gate section includes:
an upper part having a first transmission gate and a second transmission gate connected in series, the first transmission gate being controlled in accordance with a clock signal, and the second transmission gate being controlled in accordance with an enable clock signal, and
a lower part having a third transmission gate and a fourth transmission gate connected in series, the third transmission gate being controlled complementarily to the first transmission gate in accordance with the clock signal, and the fourth transmission gate being controlled complementarily to the second transmission gate in accordance with the enable clock signal.

2. The apparatus of claim 1, wherein, when the enable clock signal is at a logic high level, the apparatus operates as an edge triggered flip-flop in a rising edge mode with respect to the clock signal, and when the enable clock signal is at a logic low level, the apparatus operates as an edge triggered flip-flop in a falling edge mode with respect to the clock signal.

3. The apparatus of claim 1,
wherein, in each transmission gate section, when the enable clock signal is at a logic high level, the second transmission gate is turned on, and the fourth transmission gate is turned off, and when the enable clock signal is at a logic low level, the second transmission gate is turned off, and the fourth transmission gate is turned on.

4. The apparatus of claim 3,
wherein each transmission gate section includes at least one of:
a first type of a transmission gate section in which, when the clock signal is at a logic high level, the first and second transmission gates are both turned on, and when the clock signal is at a logic low level, the third and fourth transmission gates are both turned on; and
a second type of a transmission gate section in which, when the clock signal is at the logic low level, the first and second transmission gates are both turned on, and when the clock signal is at the logic high level, the third and fourth transmission gates are both turned on.

5. The apparatus of claim 1,
wherein the first to fourth transmission gates individually include first to fourth NMOS transistors, and first to fourth PMOS transistors, each of which has the common source and drain with a corresponding one of the first to fourth NMOS transistors, and
complementary signals are input to the gates of an NMOS transistor and a PMOS transistor belonging to the same transmission gate.

6. The apparatus of claim 1, wherein the logic high level is at a power supply voltage, and the logic low level is at a ground voltage.

7. The apparatus of claim 2, wherein the apparatus is designed to operate in either the rising edge mode or the falling edge mode at the time of application of the enable clock signal at a fixed voltage.

8. The apparatus of claim 1, wherein the apparatus operates as an edge triggered flip-flop, and the at least one inverter includes an inverter serving as a D-input.

9. The apparatus of claim 1, wherein the apparatus operates as an edge triggered flip-flop, and the at least one inverter includes a series of two inverters serving as a clock input.

10. The apparatus of claim 1, wherein the apparatus operates as an edge triggered flip-flop, and the at least one inverter includes an inverter serving as an enable input.

11. The apparatus of claim 1, wherein the apparatus operates as an edge triggered flip-flop, and the at least one inverter includes an inverter serving as a Q-output, and an inverter serving as an output complimentary to the Q-output.

12. The apparatus of claim 3, wherein the apparatus operates as an edge triggered flip-flop, and the at least one inverter includes a first inverter serving as a D-input, a second and third inverter connected in series serving as a clock input, a fourth inverter serving as an enable input, a fifth inverter serving as a Q-output, and a sixth inverter serving as an output complimentary to the Q-output.

13. The apparatus of claim 4, wherein the apparatus operates as an edge triggered flip-flop, and the at least one inverter includes a first inverter serving as a D-input, a second and third inverter connected in series serving as a clock input, a fourth inverter serving as an enable input, a fifth inverter serving as a Q-output, and a sixth inverter serving as an output complimentary to the Q-output.

14. A method comprising:
connecting a first transmission gate to a second transmission gate in series, wherein the first transmission gate is controlled in accordance with a clock signal, and the second transmission gate is controlled in accordance with an enable clock signal; and
connecting a third transmission gate to a fourth transmission gate, wherein the third transmission gate is controlled complementarily to the first transmission gate in accordance with the clock signal, and the fourth transmission gate is controlled complementarily to the second transmission gate in accordance with the enable clock signal, thereby forming an edge triggered flip-flop.

15. The method of claim 14, wherein, when the enable clock signal is at a logic high level, the edge triggered flip-flop operates in a rising edge mode with respect to the clock signal, and when the enable clock signal is at a logic low level, the edge triggered flip-flop operates in a falling edge mode with respect to the clock signal.

16. The method of claim 14, wherein, in each transmission gate section,
when the enable clock signal is at a logic high level, the second transmission gate is turned on, and the fourth transmission gate is turned off, and
when the enable clock signal is at a logic low level, the second transmission gate is turned off, and the fourth transmission gate is turned on.

17. The method of claim 16, wherein each transmission gate section includes at least one of:
a first type of a transmission gate section in which, when the clock signal is at a logic high level, the first and second transmission gates are both turned on, and when the clock signal is at a logic low level, the third and fourth transmission gates are both turned on; and
a second type of a transmission gate section in which, when the clock signal is at the logic low level, the first and second transmission gates are both turned on, and when the clock signal is at the logic high level, the third and fourth transmission gates are both turned on.

18. The method of claim 14, wherein the logic high level is at a power supply voltage, and the logic low level is at a ground voltage.

19. The method of claim 15, wherein the edge triggered flip-flop is designed to operate in either the rising edge mode or the falling edge mode at the time of application of the enable clock signal at a fixed voltage.

20. The method of claim 14, including forming a first inverter serving as a D-input, forming a second and third inverter connected in series serving as a clock input, forming a fourth inverter serving as an enable input, forming a fifth inverter serving as a Q-output, and forming a sixth inverter serving as an output complimentary to the Q-output.
